(19) United States
(12) Patent Application Publication
(10) Pub. No.: US 2012/0042925 A1
(43) Pub. Date: Feb. 23, 2012

(54) Solar Cell String And Solar Module Equipped With Such Solar Cell String

(75) Inventor: Andreas Pfennig, Liepzig (DE)

(73) Assignee: Q-CELLS SE, Bitterfeld-Wolfen, OT Thalheim (DE)

(21) Appl. No.: 13/201,497

(22) PCT Filed: Jan. 11, 2010
(86) PCT No.: PCT/DE2010/705003

§ 371 Date: Sep. 13, 2011

(30) Foreign Application Priority Data
Feb. 16, 2009 (DE) 102009003491.9-33

(51) Int. Cl. H01L 31/042

(52) U.S. Cl. 136/244

(57) ABSTRACT

A solar cell string contains a solar cell (1), formed by a wafer substrate (10) having a flat electrode contact segment (11), having a further solar cell (2) disposed adjacent to the solar cell (1), formed by a further wafer substrate (20) having a further flat electrode contact segment (21) and at least one cell connector (3) having a cell connector width and a cell connector thickness (3d) oriented substantially perpendicular to the electrode contact segments (11, 21). The cell connector extends along an extension direction (E) from the electrode contact segment (11) of the solar cell (1) to the further electrode contact segment (21) of the further solar cell (2), wherein the cell connector (3) electrically connects electrodes of the solar cell (1) to further electrodes of the further solar cell (2). The cell connector thickness (3d) of the linear cell connector (3) tapers down at least in segments along the extension direction (E) thereof, starting from the solar cell (1), in the direction of the further solar cell (2).

### TECHNICAL FIELD

The present invention relates to a solar cell string comprising a plurality of interconnected solar cells. Furthermore, the present invention relates to a solar module constructed from solar strings according to the invention.

### BACKGROUND

Unlike in the case of thin-film solar modules, during the production of which a monolithic interconnection of the individual solar cells to form a solar module can be realized, wafer solar cells are usually electrically interconnected in a hybrid construction via cell connectors, for example in the form of soldering ribbons. A plurality of solar cells interconnected in this way is usually referred to as a solar cell string, wherein a plurality of strings arranged alongside one another are electrically coupled to one another in order to form a solar module.

Such a solar cell string comprises a solar cell, made of a wafer substrate with a planar electrode contact section, for example in the form of a busbar, a further solar cell, adjacent to the solar cell, made of a further wafer substrate with a planar further electrode contact section, and at least one ribbon-shaped cell connector, extending along a direction of extension from the electrode contact section of the solar cell to the further electrode contact section of the further solar cell. Said ribbon-shaped cell connector has a cell connector width and a cell connector thickness oriented substantially perpendicular to the electrode contact sections, where in the cell connector electrically interconnects electrodes of the solar cell with further electrodes of the further solar cell.

In order to save costly semiconductor material in the form of silicon, for example, solar cells are being produced on ever thinner wafer substrates. Substrate thicknesses of significantly less than 500 μm such as, for example, 300 μm and 160 μm, have become customary in the meantime. These solar cell substrates are becoming more and more fragile mechanically. For the hybrid interconnection by means of ribbon-shaped cell connectors in the form of solder ribbons, the soldering process entails a significant mechanical loading. Said soldering ribbons are embodied as copper ribbons, for example, which are coated with a soft solder or with a readily solderable metallization layer. The coefficients of thermal expansion of the metallic soldering ribbons differ in comparison with silicon in such a way that mechanical stresses arising during cooling after the soldering process can lead to a visually discernable flexure of the wafers or even to fracture of the wafers. In order to keep these mechanical stresses low, use is made of soldering ribbons which, for their part, have a thickness that is less than or equal to the wafer thickness used. With ever thinner soldering ribbons, however, the ohmic resistance thereof increases. Compensation of the decreasing conductivity by increasing the soldering ribbon width is possible only to a limited extent, since a significant overlap of the soldering ribbons beyond the width of the busbars contact-connected on the solar cells would lead to additional shading of the light entrance zones on the solar cell. However, this would lead to an undesirable decrease in the solar cell efficiency.

### SUMMARY OF THE INVENTION

Consequently, the present invention is based on the object of providing a solar cell string which makes it possible to use thin wafer solar cells, wherein the efficiency of said solar cells is intended to be influenced as little as possible by the electrical contact-connection with cell connectors.

The invention provides for the cell connector thickness of the ribbon-shaped cell connector to increase at least in sections along its direction of extension, starting from the solar cell towards the further solar cell.

With the increase in the thickness of the cell connector, the mechanical stresses to be absorbed by the wafer substrate increase. At the same time, the ohmic resistance of the cell connector decreases. By virtue of the fact that the increase in thickness is not present along the entire cell connector, but rather in sections, the increase in the mechanical stresses that arise is limited. At the same time, the series resistance of the cell connector decreases.

Preferably, the cell connector thickness increases in the current flow direction of the solar cell. This entails the advantage that more conductor area is available to the increasing electric current.

Suitable value ranges for the increase in the cell connector thickness of the ribbon-shaped cell connector are factors of 1.5 to 3, preferably a factor of 2. These ranges already lead to a significant increase in the efficiency of the solar cells of the string without introducing mechanical stresses to an excessively great extent.

Preferably, the electrode contact section and/or the further electrode contact section is embodied as a busbar having a busbar width. The busbars are usually embodied as metal contacts burned into the wafer substrate. For front-contact wafer solar cells, customary busbar widths are approximately 2 mm if two busbars are provided. Busbar widths of approximately 1.5 mm are used in the case of three busbars.

Advantageously, the cell connector width of the cell connector is substantially smaller than or equal to the busbar width. As a result, the ribbon-shaped cell connector can be arranged on the busbars in such a way that the cell connector only overlaps the busbars of the solar cells. This ensures that no reduction of the solar cell efficiency by the shading of parts of the light entry surface of the solar cells by the ribbon-shaped cell connectors occurs. The choice of the cell connector width is greatly dependent on the cell connector positioning accuracy available in the respective mounting process. In addition, narrow cell connectors can tend toward assuming a slightly saber-shaped contour in the manner governed by production. Such a curved contour makes it difficult, in the case of rectilinear busbars, for the cell connectors to be situated exclusively on the busbars.

In one particularly suitable embodiment, when viewed in the direction of the cell connector thickness, the ribbon-shaped cell connector comprises a plurality of ribbon-shaped connector elements placed on top of one another, which overlap in sections along the direction of extension on an overlap section of the solar cell and along a further overlap section of the further solar cell.

Furthermore, it is advantageous if the ribbon-shaped connector elements each have a thickness which is smaller than or equal to the wafer substrate thickness. By virtue of this restriction, the mechanical stress introduced by the individual connector elements after a soldering process is limited to a sufficient extent. This prevents excessive flexure or even fracture of the wafer substrate. Furthermore, such thin ribbon-shaped connector elements in the form of soldering ribbons have a lower heat capacity, such that correspondingly lower quantities of thermal energy have to be introduced during the soldering process.

For the embodiment of the ribbon-shaped cell connector constructed from connector elements it is preferably provided that the overlap section and the further overlap section are arranged adjacent to one another on the solar cells and each encompass 10 to 80%, preferably 25 to 35%, of the extension length of the respective electrode contact sections. By way of the specific selection of the length, the magnitude of mechanical stresses that occur can be influenced and optimized for the respective boundary conditions.

Preferably, the solar cells in all embodiments are designed as front-contact solar cells with light entry sides, wherein the light entry sides comprise a plurality of electrode contact sections in the form of busbars which are each provided with a ribbon-shaped cell connector. In a series interconnection of solar cells, in a known manner, the cell connectors of the solar cell string then run from the front sides of the solar cells to the rear sides of the adjacent solar cells.

It is particularly suitable, when using front-contact cells, that, when viewed from above onto the light entry sides of the solar cell, the plurality of ribbon-shaped connector elements feature a lower ribbon-shaped connector element, which is arranged offset in the direction of the further solar cell and which is positioned beneath an upper connector element positioned along the electrode contact section of the solar cell. In this way, the modular construction of the ribbon-shaped cell connectors from a plurality of ribbon-shaped connector elements cannot be discerned when viewed from the light entry side. This results in a more harmonious overall picture with regard to the optical elegance of the solar cell string. It is possible, of course, to combine different ribbon-shaped connector elements with one another. As already mentioned, ribbon-shaped connector elements can have a copper ribbon provided with soft solder and/or a solderable metal coating. It is likewise conceivable to use different types of soft solder.

The solar cell strings described are particularly suitable for being assembled for the production of solar modules. For this purpose, a plurality of interconnected solar cell strings are encapsulated in a weather-proof manner to form a module in a known manner.

### BRIEF DESCRIPTION OF THE DRAWINGS

Further features and properties of the invention will be explained in greater detail in connection with the explanations concerning a concrete embodiment shown in the following drawings.

Therein:

FIG. 1 shows a schematic side view of a solar cell string, this side view not being true to scale;

FIG. 2 shows a view of the solar cell string along the arrows II illustrated in FIG. 1; and

FIG. 3 shows a view of the solar cell string along the arrows III illustrated in FIG. 1.

### DETAILED DESCRIPTION OF THE INVENTION

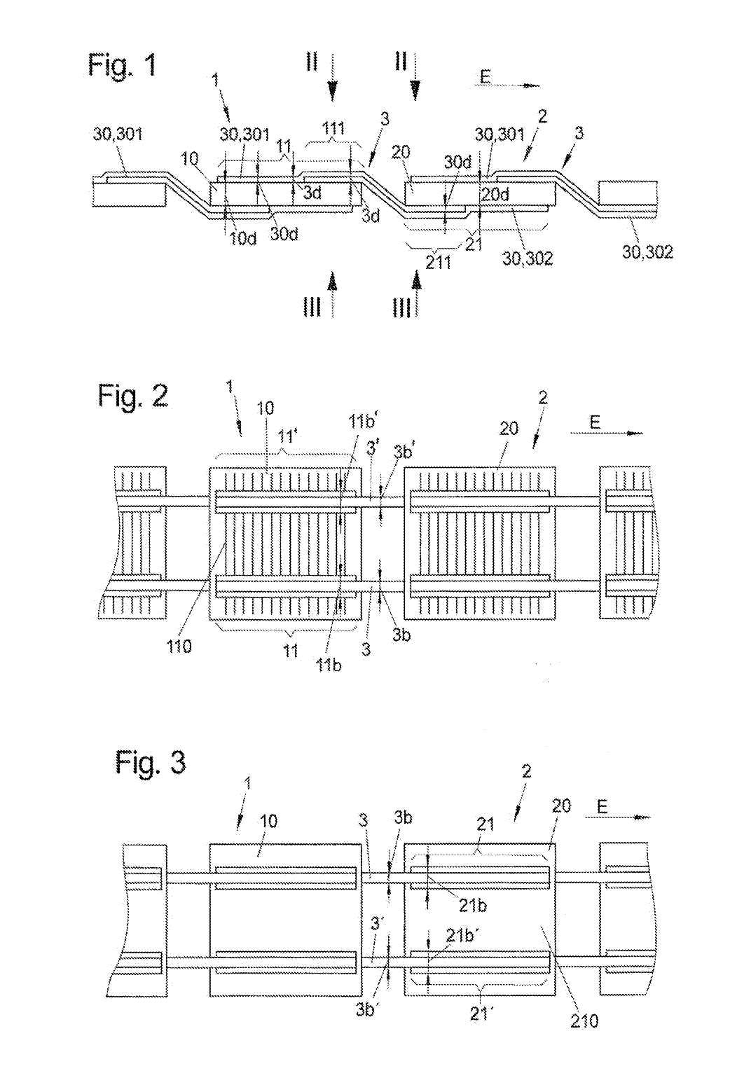

FIG. 1 shows an illustration—not true to scale—of a solar cell string constructed from front-contact solar cells 1, 2, which are produced from wafer substrates 10, 20 having substrate thicknesses 10d, 20d. Front electrodes of the solar cell 1 and rear electrodes of the adjacent further solar cell 2, said electrodes not being discernible in the side illustration in FIG. 1, are electrically interconnected by means of ribbon-shaped cell connectors 3. In this case, the ribbon-shaped cell connectors 3 extend substantially along a direction of extension E, which also corresponds to the direction of extension of the solar cell string. Each cell connector 3 is contact-connected to electrodes of the solar cell 1 via an electrode contact section 11 and to further electrodes of the further solar cell 2 via a further electrode contact section 21. The cell connectors 3 are constructed from ribbon-shaped connector elements 30 which are arranged offset as viewed along the direction of extension E of the cell connector 3 and therefore overlap in sections. This overlap is present in the overlap section 111 on the front side of the solar cell 1 and in the further overlap section 211 on the rear side of the further solar cell 2.

The connector elements 30 each have identical thicknesses 30d. Consequently, the thickness 3d of the cell connector 3 outside the overlap sections 111, 211 corresponds to the thickness 30d of a single ribbon-shaped connector element 30. In the overlap sections 111, 211, the thickness 3d of the cell connector 3 amounts to double the thickness 30d of a connector element 30. Consequently, the thickness 3d of the cell connector 3 increases in sections when viewed in the direction of extension E. The solar cells 1, 2 are arranged in such a way that the solar cell current flows in the direction of the indicated direction of extension E. This firstly ensures that an increased conductor cross-sectional area of the cell connector 3 is available to the solar cell current increasing along the direction of extension E. Secondly, on account of the lower heat capacity of the cell connector 3, less heating energy action is required for the soldering of the cell connector 3, which leads to a smaller thermal expansion of the adjacent regions of the wafer substrate 10, 20. Consequently, lower mechanical stresses occur after the soldering process between the cell connector 3 and the wafer substrate 10, 20. Better electrical conductivity and lower mechanical stresses lead to a better efficiency of the solar cells after their interconnection in a solar cell string.

In the exemplary embodiment shown here, the increase in thickness takes place abruptly from the level of the thickness 30d of a connector element 30 to double the value. The desired effect could be achieved in a similar manner by means of a continuous increase in the cell connector thickness. Said continuous increase could take place over the entire length of the cell connector 3 or else in sections.

It is expressly pointed out that the dimensions of the solar cell string as shown in FIG. 1 are illustrated in a manner greatly increased perpendicular to the direction of extension E and decreased along the direction of extension E. The substrate thicknesses 10d, 20d are preferably less than 500 μm. By way of example, it is customary for wafers to have a thickness of 300 μm or 150 μm in comparison with wafer edge lengths (length×width) of in each case many centimeters. Accordingly, the ribbon-shaped cell connectors 3 or the ribbon-shaped connector elements 30 have a length of many centimeters with thicknesses 30d which are in each case less than or equal to the abovementioned substrate thicknesses 10d, 20d. It is clear that a solar cell string comprises at least two interconnected solar cells 1, 2. This type of interconnection can—as indicated in FIG. 1—be repeated often along the direction of extension E.

FIG. 2 shows a plane view of the solar cell string from FIG. 1 along the arrow direction designated by II in FIG. 1. The light entry sides of the solar cells 1, 2 with their front electrodes 110 can be discerned schematically and in a manner not true to scale. The electrode contact sections 11, 11′ are embodied as two busbars. In the case of solar cells having two busbars 11, 11′ on the front side, these usually have busbar widths 11b, 11b′ of approximately 2 mm. In the case of a design having three busbars, the busbar width turns out to be smaller with a value of approximately 1.5 mm. As illustrated here, the cell connector width 3b, 3b′ is preferably less than the busbar width 11b, 11b′. This ensures, even taking account of mounting tolerances, that the cell connectors do not shade regions of the photoactive area of the solar cell 1 which are adjacent to the busbars 11, 11′, which would lead to an undesirable decrease in the efficiency.

FIG. 3 shows a view of the solar cell string from FIG. 1 along the arrow direction designated by III in FIG. 1. The rear sides of the solar cells 1, 2 can be discerned schematically and in a manner not true to scale. The cell connectors 3, 3′ make contact with further electrode contact sections 21, 21′—likewise embodied as busbars—for the further electrode 210, as illustrated here as an example in the form of a planar rear electrode of the solar cell 2. This construction is repeated within the solar cell string usually in the case of each of the interconnected solar cells.

List of reference symbols:
1 Solar cell
10 Wafer substrate of the solar cell
10d Substrate thickness
11, 11′ Electrode contact section—busbar
11b, 11b′ Busbar width
110 Electrodes of the solar cell
111 Overlap section on solar cell
2 Further solar cell
20 Further wafer substrate of the further solar cell
20d Substrate thickness
21, 21′ Further electrode contact section—busbar
21b, 21b′ Busbar width
210 Further electrodes of the further solar cell
211 Further overlap section on further solar cell
3, 3′ Ribbon-shaped cell connector
3b, 3b′ Cell connector width
3d Cell connector thickness
30 Ribbon-shaped connector elements
30d Thickness of the connector elements
301 Upper ribbon-shaped connector element
302 Lower ribbon-shaped connector element
E Direction of extension of the cell connector

1. Solar cell string comprising:
a solar cell (1), made of a wafer substrate (10) with a planar electrode contact section (11),
a further solar cell (2), adjacent to the solar cell (1), made of a further wafer substrate (20) with a planar further electrode contact section (21) and
at least one ribbon-shaped cell connector (3), extending along a direction of extension (E) from the electrode contact section (11) of a solar cell (1) to the further electrode contact section (21) of the further solar cell, the at least one ribbon-shaped cell connector (3) having a cell connector width (3b) and a cell connector thickness oriented substantially perpendicular to the electrode contact sections (11, 21), whereby the cell connector (3) electrically connects electrodes (110) of the solar cell (1) with further electrodes (210) of the further solar cell (2),
wherein the cell connector thickness (3d) of the ribbon-shaped cell connector (3) increases at least in sections along the direction of extension (E), starting from the solar cell (1) towards the further solar cell (2).

2. Solar cell string in accordance with claim 1, characterized in that the cell connector thickness (3d) increases in the current flow direction.

3. Solar cell string in accordance with claim 1, wherein the cell connector thickness (3d) of the ribbon-shaped cell connector (3) increases by a factor of between 1.5 and 3.

4. Solar cell string in accordance with claim 1 wherein the electrode contact section (11) and/or the further electrode contact section (21) is arranged as a busbar having a busbar width (11b,21b).

5. Solar cell string in accordance with claim 4, characterized in that the cell connector width (3b) of the cell connector (3) is substantially smaller than or equal the busbar width (11b, 21b).

6. Solar cell string in accordance with claim 5, characterized in that the ribbon-shaped cell connector (3) is positioned on the busbars (11, 21) in such a way that the cell connector (3) only overlaps with the busbars (11, 21) of the solar cells (1, 2).

7. Solar cell string in accordance with claim 1, wherein, when viewed in the direction of the cell connector thickness (3d), the ribbon-shaped cell connector (3) comprises a plurality of ribbon-shaped connector elements (30) placed on top of one another, which overlap in sections along the direction of extension (E) on an overlap section (111) of the solar cell (1) and along a further overlap section (211) of the further solar cell (2).

8. Solar cell string in accordance with claim 7, characterized in that the ribbon-shaped connector elements (30) have a thickness, which is smaller than or equal the wafer substrate thickness (10d).

9. Solar cell string in accordance with claim 7, wherein the overlap section (111) and the further overlap section (211) are arranged adjacent to one another on the solar cells (1,2) and each encompass 10% to 80%, of the extension length of the respective electrode contact sections (11, 21).

10. Solar cell string in accordance with claim 1, wherein the solar cells (1,2) are front-contact solar cells with light entry sides, whereby the light entry sides comprise a plurality of electrode contact sections (11,11′,21,21′) in the form of busbars which are each provided with a linear cell connector (3,3′).

11. Solar cell string in accordance with claim 10, characterized in that when viewed from above onto the solar cell's (1) light intake sides, the plurality of the ribbon-shaped connector elements (3) feature a lower, ribbon-shaped connector element (302), offset in the direction of the further solar cell (2), which is positioned beneath an upper connector element (301) positioned along the electrode contact section (11) on the solar cell (1).

12. Solar module comprising a plurality of interconnected solar cell strings in accordance with claim 1.

13. Solar cell string in accordance with claim 1 characterized in that the cell connector thickness (3d) of the ribbon-shaped cell connector (3) increases by a factor of 2.

14. Solar cell string in accordance with claim 7, wherein the overlap section (111) and the further overlap section (211) are arranged adjacent to one another on the solar cells (1,2) and each encompass 25% to 35% of the extension length of the respective electrode contact sections (11, 21).
